(19) United States
(12) Patent Application Publication
(10) Pub. No.: US 2025/0133892 A1
(43) Pub. Date: Apr. 24, 2025

(54) DISPLAY DEVICE AND MANUFACTURING METHOD THEREOF

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 19/001,663

(22) Filed: Dec. 26, 2024

Related U.S. Application Data
(63) Continuation of application No. PCT/JP2023/019137, filed on May 23, 2023.

(30) Foreign Application Priority Data
Jul. 28, 2022 (JP) 2022-120127

(51) Int. Cl. H10H 29/856; H10H 29/01; H10H 29/39

(52) U.S. Cl. CPC H10H 29/856; H10H 29/012; H10H 29/0363; H10H 29/39

(57) ABSTRACT

Disclosed is a display device including a substrate as well as a plurality of pixels and at least one reflective element located over the substrate. Each of the plurality of pixels has a pixel circuit and a light-emitting element, and the light-emitting element has a pixel electrode electrically connected to the pixel circuit, a first stack structure over the pixel electrode, and a common electrode over the first stack structure. At least one reflective element has a lower electrode, a second stack structure over the lower electrode, and a reflective film overlapping the second stack structure. Each of the first stack structure and the second stack structure includes a plurality of inorganic semiconductor layers.

This application is a Continuation of International Patent Application No. PCT/JP2023/019137, filed on May 23, 2023, which claims the benefit of priority to Japanese Patent Application No. 2022-120127, filed on Jul. 28, 2022, the entire contents of which are incorporated herein by reference.

### FIELD

An embodiment of the present invention relates to a display device, a lighting device, and a manufacturing method thereof. For example, an embodiment of the present invention relates to a display device and a lighting device including a light-emitting element containing an inorganic semiconductor material and a manufacturing method thereof.

### BACKGROUND

In recent years, light-emitting elements containing inorganic semiconductors (inorganic LEDs) have been used in a variety of lighting devices and display devices. Since inorganic LEDs are capable of providing high luminance and have a long lifetime, the use of inorganic LEDs enables the production of highly reliable display devices and lighting devices having low power consumption (see, for example, International Patent Application Publication No. 2021/161126 and U.S. Pat. No. 10,937,815).

### SUMMARY

An embodiment of the present invention is a display device. The display device includes a substrate as well as a plurality of pixels and at least one reflective element located over the substrate. Each of the plurality of pixels includes a pixel circuit and a light-emitting element, and the light-emitting element includes a pixel electrode electrically connected to the pixel circuit, a first stack structure over the pixel electrode, and a common electrode over the first stack structure. The at least one reflective element includes a lower electrode, a second stack structure over the lower electrode, and a reflective film overlapping the second stack structure. Each of the first stack structure and the second stack structure includes a plurality of inorganic semiconductor layers.

An embodiment of the present invention is a lighting device. The lighting device includes a substrate as well as a plurality of light-source units and at least one reflective element located over the substrate. Each of the plurality of light-source units includes a light-source circuit and a light-emitting element, and the light-emitting element includes a first electrode electrically connected to the light-source circuit, a first stack structure over the first electrode, and a second electrode over the first stack structure. The at least one reflective element includes a lower electrode, a second stack structure over the lower electrode, and a reflective film overlapping the second stack structure. Each of the first stack structure and the second stack structure includes a plurality of inorganic semiconductor layers.

An embodiment of the present invention is a manufacturing method of a display device. The manufacturing method includes: forming a plurality of pixel circuits over a substrate; forming, over the plurality of pixel circuits, a leveling film having a plurality of openings; forming, over the leveling film, a conductive film electrically connected to the plurality of pixel circuits through the plurality of openings; bonding a stacking structure located over a first transfer substrate and containing a plurality of inorganic semiconductor layers to the conductive film; pealing the first transfer substrate; processing the stacking structure to form a plurality of first stack structures and at least one second stack structure; processing the conductive film to form a plurality of pixel electrodes respectively overlapping the plurality of first stack structures and electrically connected to the plurality of pixel circuits, respectively, and a lower electrode overlapping the at least one second stack structure and electrically separated from each of the plurality of pixel circuits; forming a reflective film overlapping the at least one second stack structure; forming a partition wall embedding the at least one second stack structure and the reflective film and covering edge portions of the plurality of first stack structures; and forming, over the plurality of first stack structures and the at least one second stack structure, a common electrode electrically connected to the plurality of first stack structures and spaced away from the reflective film.

An embodiment of the present invention is a manufacturing method of a lighting device. The manufacturing method includes: forming a plurality of light-source circuits over a substrate; forming, over the plurality of light-source circuits, a leveling film having a plurality of openings; forming, over the leveling film, a conductive film electrically connected to the plurality of light-source circuits through the plurality of openings; bonding a stacking structure located over a first transfer substrate and containing a plurality of inorganic semiconductor layers to the conductive film; peeling the first transfer substrate; processing the stacking structure to form a plurality of first stack structures and at least one second stack structure; processing the conductive film to form a plurality of first electrodes respectively overlapping the plurality of first stack structures and electrically connected to the plurality of light-source circuits, respectively, and a lower electrode overlapping the at least one second stack structure and electrically separated from each of the plurality of light-source circuits; forming a reflective film overlapping the at least one second stack structure; forming a partition wall embedding the at least one second stack structure and the reflective film and covering edge portions of the plurality of first stack structures; and forming, over the plurality of first stack structures and the at least one second stack structure, a second electrode electrically connected to the plurality of first stack structures and spaced away from the reflective film.

### BRIEF DESCRIPTION OF DRAWINGS

FIG. 1 is a schematic top view of a display device according to an embodiment of the present invention.

FIG. 2A is a schematic top view of a display device according to an embodiment of the present invention.

FIG. 2B is a schematic top view of a display device according to an embodiment of the present invention.

FIG. 3A is a schematic top view of a display device according to an embodiment of the present invention.

FIG. 3B is a schematic top view of a display device according to an embodiment of the present invention.

FIG. 4A is a schematic top view of a display device according to an embodiment of the present invention.

FIG. 4B is a schematic top view of a display device according to an embodiment of the present invention.

FIG. 5 is a schematic cross-sectional view of a display device according to an embodiment of the present invention.

FIG. 6A is a schematic cross-sectional view of a display device according to an embodiment of the present invention.

FIG. 6B is a schematic cross-sectional view of a display device according to an embodiment of the present invention.

FIG. 7 is a schematic cross-sectional view of a display device according to an embodiment of the present invention.

FIG. 8 is a schematic cross-sectional view of a display device according to an embodiment of the present invention.

FIG. 9 is a schematic cross-sectional view for explaining a manufacturing method of a display device according to an embodiment of the present invention.

FIG. 10 is a schematic cross-sectional view for explaining a manufacturing method of a display device according to an embodiment of the present invention.

FIG. 11 is a schematic cross-sectional view for explaining a manufacturing method of a display device according to an embodiment of the present invention.

FIG. 12 is a schematic cross-sectional view for explaining a manufacturing method of a display device according to an embodiment of the present invention.

FIG. 13 is a schematic cross-sectional view for explaining a manufacturing method of a display device according to an embodiment of the present invention.

FIG. 14 is a schematic cross-sectional view for explaining a manufacturing method of a display device according to an embodiment of the present invention.

FIG. 15 is a schematic cross-sectional view for explaining a manufacturing method of a display device according to an embodiment of the present invention.

FIG. 16 is a schematic cross-sectional view for explaining a manufacturing method of a display device according to an embodiment of the present invention.

FIG. 17 is a schematic cross-sectional view for explaining a manufacturing method of a display device according to an embodiment of the present invention.

FIG. 18 is a schematic cross-sectional view for explaining a manufacturing method of a display device according to an embodiment of the present invention.

FIG. 19 is a schematic cross-sectional view for explaining a manufacturing method of a display device according to an embodiment of the present invention.

FIG. 20 is a schematic cross-sectional view for explaining a manufacturing method of a display device according to an embodiment of the present invention.

FIG. 21 is a schematic cross-sectional view for explaining a manufacturing method of a display device according to an embodiment of the present invention.

### BRIEF DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, the drawings are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the embodiments according to the present invention, when a plurality of films is simultaneously formed in the same process, these films have the same layer structure, the same material, and the same composition. Hence, these films are defined as existing in the same layer.

### First Embodiment

In this embodiment, a structure of a display device 100 according to an embodiment of the present invention is explained.

### 1. Overall Structure

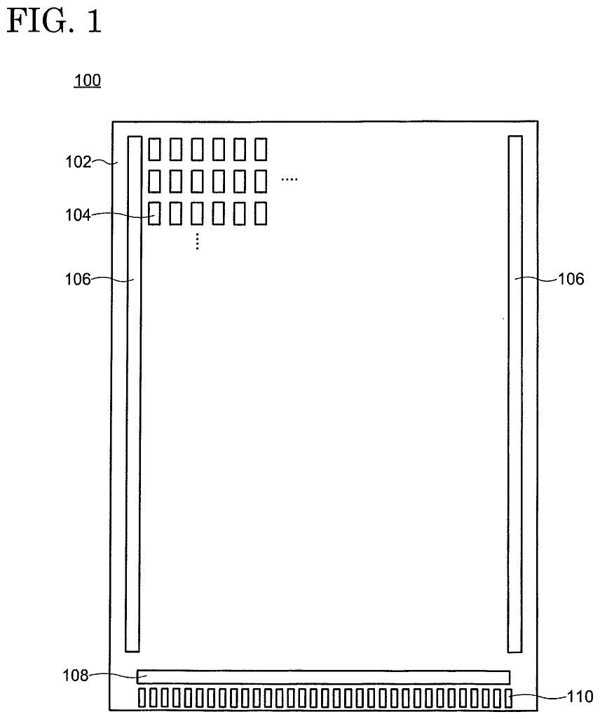

FIG. 1 shows a schematic top view of the display device 100. As shown in FIG. 1, the display device 100 has a substrate 102 over which a plurality of pixels 104 and a plurality of reflective elements (not illustrated in FIG. 1) described below are provided. A minimum region encompassing all of the pixels 104 and the reflective elements and a region surrounding this region are defined as a display region and a peripheral region, respectively.

Driver circuits are provided in the peripheral region to drive the pixels 104. In the example shown in FIG. 1, two scanning-line driver circuits 106 sandwiching the plurality of pixels 104 and a signal-line driver circuit 108 including an analog switch and the like are provided. Wirings which are not illustrated extend to a side of the substrate 102 from the scanning-line driver circuits 106 and the signal-line driver circuits 108 and are exposed at an edge portion of the substrate 102 to form terminals 110. The terminals 110 are electrically connected to a connector such as a flexible printed circuit (FPC) board which is not illustrated, and power and video signals are supplied to the display device 100 from an external circuit through the connector. Desired images are displayed on the display region according to the video signals by driving the pixels 104 serving as the smallest unit providing color information.

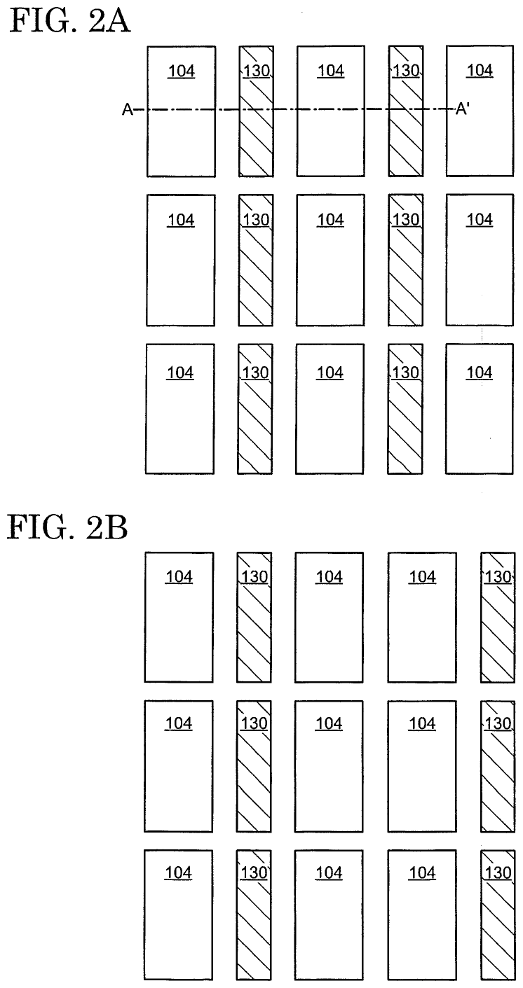

An enlarged top view of a portion of the display region is schematically shown in FIG. 2A. As can be understood from FIG. 2A, at least one or a plurality of reflective elements 130 is further provided in the display region together with the plurality of pixels 104. When a plurality of reflective elements 130 is provided, the plurality of pixels 104 and the plurality of reflective elements 130 may be arranged in a matrix shape having a plurality of rows and columns as a whole. In FIG. 2A, six pixels 104 and four reflective elements 130 arranged in a matrix shape with three rows and five columns are illustrated. The plurality of pixels 104 and the plurality of reflective elements 130 may be arranged to alternate in the row direction and/or the column direction as shown in FIG. 2A. Alternatively, the plurality of pixels 104 may be arranged between two adjacent reflective elements 130, or the plurality of reflective elements 130 may be arranged between two adjacent pixels 104. For example, two pixels 104 may be sandwiched between two adjacent reflective elements 130 in the row direction as shown in FIG. 2B.

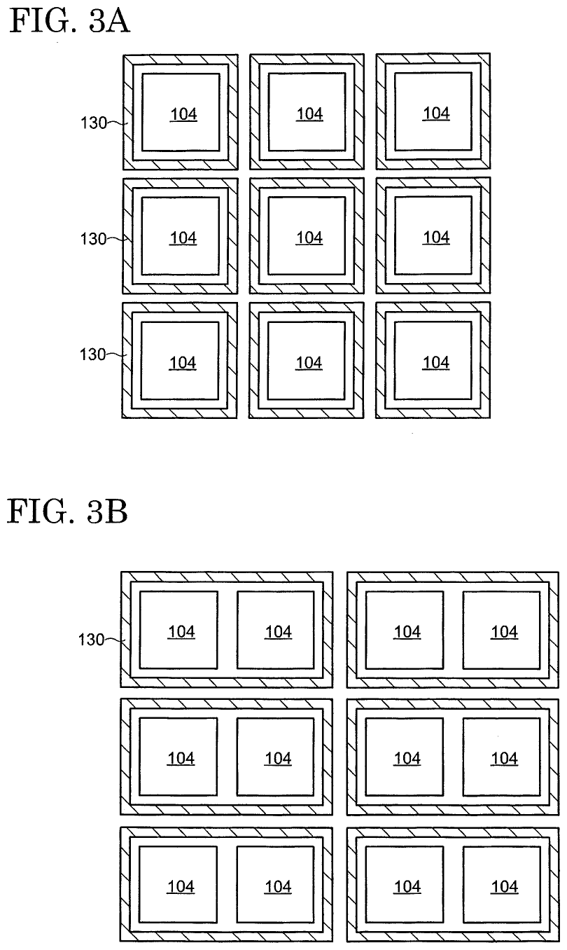

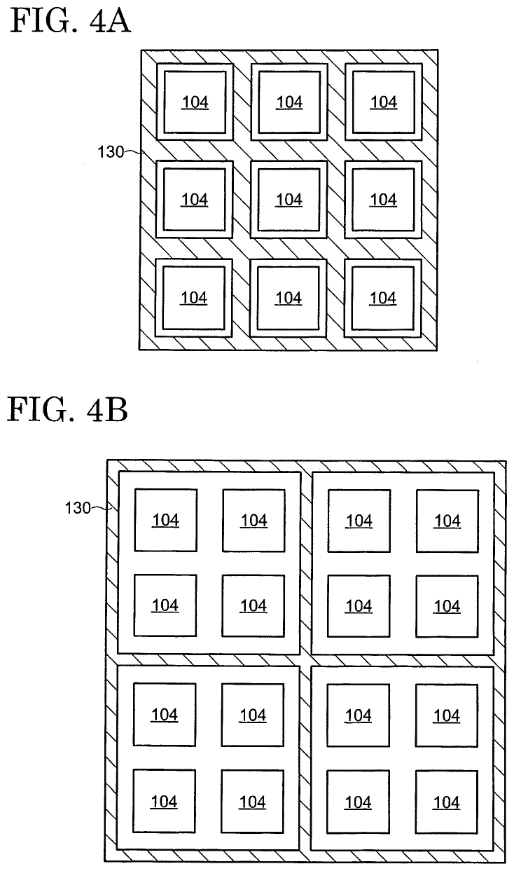

Alternatively, each of the plurality of reflective elements 130 may be formed so as to have an opening surrounding one or a plurality of pixels 104 as shown in FIG. 3A and FIG. 3B. The number of pixels 104 surrounded by one reflective element 130 is arbitrary, and each reflective element 130 may surround three or more pixels 104. Furthermore, the number of pixels 104 surrounded by the reflective element 130 may also be the same or different within the display region. Alternatively, one or a plurality of reflective elements 130 having a lattice shape may be provided in the display device 100 as shown in FIG. 4A and FIG. 4B. That is, a plurality of openings may be provided in each reflective element 130, and one or a plurality of pixels 104 may be arranged in each opening. Hereinafter, although a configuration is explained as a representative example in which the plurality of pixels 104 and the plurality of reflective elements 130 are arranged alternately in the row direction as shown in FIG. 2A, the following explanation may be applied to other arrangements as well.

### 2. Substrate and Counter Substrate

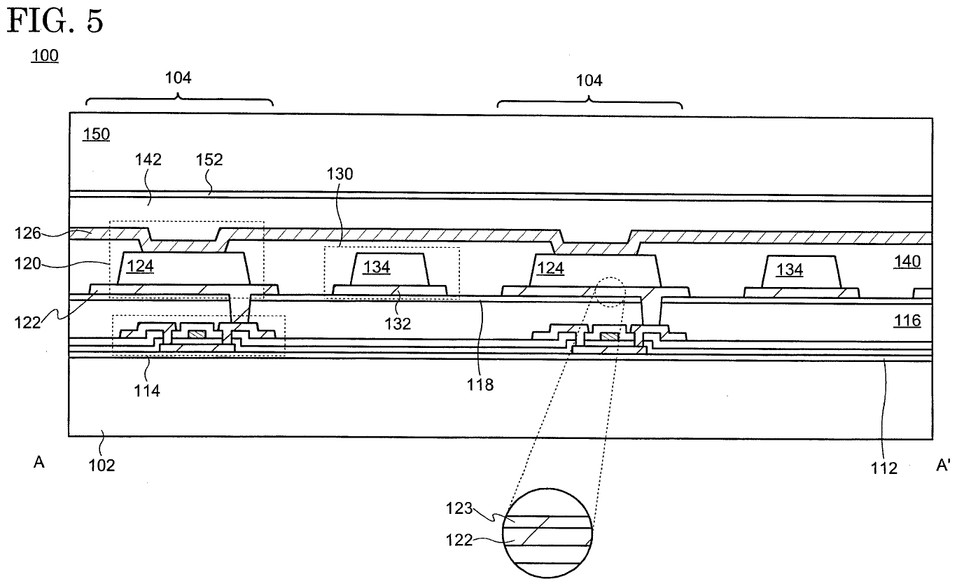

A schematic view of the cross sections along the chain line A-A′ in FIG. 2A is shown in FIG. 5. As shown in FIG. 5, the display device 100 has, in addition to the substrate 102, a counter substrate 150 facing the substrate 102, between which the pixels 104 and the reflective elements 130 are provided. As the substrate 102, a glass substrate, a quartz substrate, a single-crystal silicon substrate or the like may be used. Alternatively, a substrate containing a polymer such as a polyimide, a polyamide, or a polycarbonate may be used. Similarly, a glass substrate, a quartz substrate, a substrate containing a polymer or the like may be used as the counter substrate 150. The substrate 102 and the counter substrate 150 may be flexible. As described below, the display device 100 may be configured so that the light generated by the pixels 104 is extracted through the counter substrate 150. In this case, the counter substrate 150 is configured to transmit visible light.

### 3. Pixel

### (1) Pixel Circuit

Each pixel 104 is provided with a pixel circuit to control the pixel 104 over the substrate 102 either directly or through an undercoat 112 functioning as a barrier layer. The undercoat 112 is a film for preventing impurities such as alkali metal ions from entering the pixel circuits and the like from the substrate 102 and may be composed of one or a plurality of films containing a silicon-containing inorganic compound such as silicon nitride and silicon oxide.

There are no restrictions on the configuration of the pixel circuit, and the pixel circuit may be composed of one or a plurality of transistors and capacitor elements according to the driving method of the pixel 104. There are also no restrictions on the structure of the transistors included in the pixel circuit, and one or both of bottom-gate transistors and top-gate transistors may be combined as appropriate. There are also no restrictions on the material contained in the active layer of the transistor, and the pixel circuit may be configured using a silicon transistor containing silicon in the active layer or a transistor containing an oxide semiconductor such as indium-gallium oxide and indium-gallium-zinc oxide in the active layer.

A leveling film 116 is provided over the pixel circuit to provide a flat top surface. The leveling film 116 includes a polymeric material such as an acrylic resin, an epoxy resin, a polyimide resin, and a polysiloxane resin. As an optional component, a protective insulating film 118 composed of one or a plurality of films containing a silicon-containing inorganic compound may be disposed over the leveling film 116.

### (2) Light-Emitting Element

The pixel 104 is further provided with a light-emitting element 120 electrically connected to the pixel circuit. The light-emitting element 120 includes, as fundamental components, a pixel electrode 122, a first stack structure 124 over the pixel electrode 122, and a common electrode 126 over the first stack structure 124. In the example shown in FIG. 5, the pixel electrode 122 is connected to the transistor 114 in the pixel circuit through an opening in the leveling film 116 and the protective insulating film 118, thereby electrically connecting the pixel circuit to the light-emitting element 120.

The pixel electrode 122 is an electrode injecting carriers (holes or electrons) into the first stack structure 124 and at the same time reflecting the light emitted from the first stack structure 124 toward the common electrode 126 side. The pixel electrode 122 includes a conductive oxide exhibiting a transmitting property with respect to visible light, such as a mixed oxide of indium and tin (ITO) and a mixed oxide of indium and zinc (IZO), a metal (0-valent metal) such as silver and aluminum, or an alloy of these metals, for example. The pixel electrode 122 may have either a single-layer structure or a stacked-layer structure. When the pixel electrode 122 contains a light-transmitting conductive oxide, a structure may be employed in which a film containing a light-transmitting conductive oxide and a film containing a metal are stacked, and the latter may be used to reflect the light. Since the light from the light-emitting element 120 is reflected by the pixel electrode 122 and extracted from the common electrode 126 side, the film containing a metal is formed to have a thickness sufficient to not transmit visible light or more.

As shown in the enlarged view in FIG. 5, a conductive adhesive layer 123 may be provided over the pixel electrode 122 to improve adhesion with the first stack structure 124. For the conductive adhesive layer 123, an alloy such as solder or a metal such as gold, silver, copper, and nickel may be used, for example.

The common electrode 126 is provided across the plurality of pixels 104. That is, the common electrode 126 is shared by the plurality of pixels 104. The common electrode 126 is electrically connected to the first stack structures 124 of the plurality of pixels 104 and is arranged so as not to be electrically or physically connected to a second stack structure 134 (described below) of the reflective element 130.

The common electrode 126 is configured to inject carriers into the first stack structure 124 and transmit the light emitted from the first stack structure 124. Specifically, the common electrode 126 is configured to include a conductive oxide transmitting visible light such as ITO or IZO or a metal (0-valent metal) such as aluminum, silver, and magnesium. When the common electrode 126 contains a 0-valent metal, the common electrode 126 is provided with a thickness sufficient to transmit visible light.

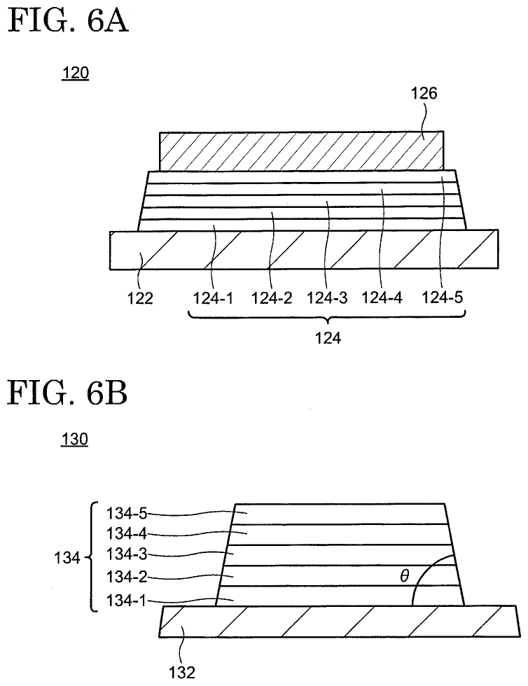

A schematic cross-sectional view of the light-emitting element 120 is shown in FIG. 6A. As shown in FIG. 6A, the first stack structure 124 is structured by stacking a plurality of functional layers containing an inorganic semiconductor. As the inorganic semiconductor, a compound containing a Group 13 element and a Group 15 element is represented. More specifically, a semiconductor containing aluminum, gallium, and/or indium as well as nitrogen, phosphorus, and/or arsenic are represented. Typically, a gallium-based material is represented. For example, a gallium nitride-based material such as gallium nitride (GaN), aluminum gallium nitride (AlGaN), and indium gallium nitride (InGaN) and gallium phosphide-based material such as gallium phosphide (GaP) and aluminum indium gallium phosphorus (AlGaInP) are exemplified. Each functional layer may contain further a dopant. As the dopant, an element such as silicon, germanium, magnesium, zinc, cadmium, and beryllium is represented. The addition of these elements enables valence electron control of each functional layer, by which not only can the intrinsic property (i-type) be maintained but also a band gap can be controlled and p-type or n-type conductivity can be imparted.

The first stack structure 124 is structured by combining a plurality of functional layers so as to be injected with carriers from the pixel electrode 122 and the common electrode 126 and to allow the carriers to recombine therein to emit light. There is no restriction on the number of functional layers, and the first stack structure may have at least a hole-transporting layer, an electron-transporting layer, and an emission layer. For example, when the pixel electrode 122 and the common electrode 126 respectively function as an anode and a cathode for respectively injecting holes and electrons, the first stack structure 124 may be composed of one or two functional layers 124-1 and 124-2 having p-type conductivity, one or two functional layers 124-4 and 124-5 having n-type conductivity, and a functional layer 124-3 functioning as the emission layer as shown in FIG. 6A. For example, the functional layers 124-1 and 124-2 respectively containing p-GaN and p-AlGaN and the functional layers 124-4 and 124-5 respectively containing n-AlGaN and n-GaN may be provided as well as the functional layer 124-3 containing InGaN, GaAs, InP, GaN, or the like as the emission layer therebetween. When the pixel electrode 122 and the common electrode 126 respectively function as a cathode and an anode, the stacking order of the aforementioned functional layers may be reversed.

The functional layer 124-3 functioning as the emission layer may have a monolayer structure or a quantum well structure. The quantum well structure is a structure in which a plurality of thin films having different band gaps and each having a thickness of approximately 1 to 5 nm are alternately stacked, and alternating layers of InGaN and GaN, alternating layers of GaInAsP and InP, alternating layers of AlInAs and InGaAs, and the like are exemplified.

### 4. Reflective Element

The reflective element 130 is an electrically floating element having a function to reflect a portion of the light emitted from the first stack structure 124 of the light-emitting element 120 toward the counter substrate 150 side. The light emitted from the light-emitting element 120 travels almost isotropically from the functional layer functioning as the emission layer. However, when the travelling direction exceeds a certain angle with respect to the normal of the substrate 102, the light is repeatedly and totally reflected between the substrate 102 and the counter substrate 150 and then decays. Therefore, a portion of the light produced by the light-emitting element 120 cannot be extracted. However, since the travelling direction of the light emitted from the first stack structure 124 at a large angle with respect to the normal of the substrate 102 can be changed upward (toward the counter substrate 150 side) by providing the reflective element 130, the total reflection is suppressed, thereby improving the light-extraction efficiency, that is, efficiency of the display device 100, and reducing power consumption.

As shown in FIG. 5, the reflective element 130 includes a lower electrode 132 and the second stack structure 134 over the lower electrode 132. As described below, the lower electrode 132 is formed in the same process as the pixel electrode 122. Therefore, the lower electrode 132 may have the same structure as the pixel electrode 122. That is, the composition, the number and stacking order of functional layers, and the thickness may be identical between the pixel electrode 122 and the lower electrode 132. Similarly, the second stack structure 134 is formed by the same process as the first stack structure 124. Therefore, the second stack structure 134 may have the same structure as the first stack structure 124. In other words, the composition, the number and stacking order of the functional layers, and the thickness may be identical between the first stack structure 124 and the second stack structure 134. For example, when the first stack structure 124 has the functional layers 124-1 to 124-5 in order from the pixel electrode 122 side, the second stack structure 134 is structured by stacking the functional layers 134-1 to 134-5 having the same composition and structure as these functional layers 121-1 to 121-5, respectively, in order from the lower electrode 132 side (FIG. 6B). Although not illustrated, the conductive adhesive layer 123 may also be provided between the lower electrode 132 and the second stack structure 134, similar to the pixel 104.

A partition wall 140 is provided over the first stack structure 124 and the second stack structure 134. The partition wall 140 is formed so as to embed the lower electrode 132 and the second stack structure 134 and not to expose the second stack structure 134. With this structure, the second stack structure 134 is spaced away from the common electrode 126 through the partition wall 140. On the other hand, the partition wall 140 is provided to cover the edge portion of the first stack structure 124 and expose other portions in the pixel 104. This structure allows an electrical connection between the first stack structure 124 and the common electrode 126.

The partition wall 140 contains a polymeric material such as an acrylic resin, an epoxy resin, a siloxane resin, and a polyimide resin. Therefore, the refractive index of the partition wall 140 is approximately 1.5 to 1.8. On the other hand, since the second stack structure 134 is composed of the plurality of functional layers including an inorganic semiconductor similar to the first stack structure 124, the refractive index thereof is high, for example, approximately 2.2 to 2.5, reflecting the characteristics of inorganic semiconductors. Therefore, a large difference in refractive index between the partition wall 140 and the second stack structure 134 causes the Fresnel reflection, and as a result, the light emitted from the first stack structure 124 can be reflected.

In order to reflect the light more efficiently toward the counter substrate 150 side, the second stack structure 134 is preferably configured so that side surfaces thereof are inclined from the normal of the lower electrode 132 (see FIG. 6B). That is, it is preferred to configure the second stack structure 134 so as to have a taper shape in which a width thereof (the length in the plane parallel to the top surface of the lower electrode 132) decreases with increasing distance from the lower electrode 132. The angle θ between the top surface of the lower electrode 132 and the side surface of the second stack structure 134 is selected from a range equal to or greater than 70° and less than 90° or equal to or greater than 80° and less than 90°, for example. As described below, the first stack structure 124 and the second stack structure 134 are formed in the same process. Accordingly, the angle between the top surface of the pixel electrode 122 and the side surface of the first stack structure 124 is also the same as or substantially the same as the angle θ.

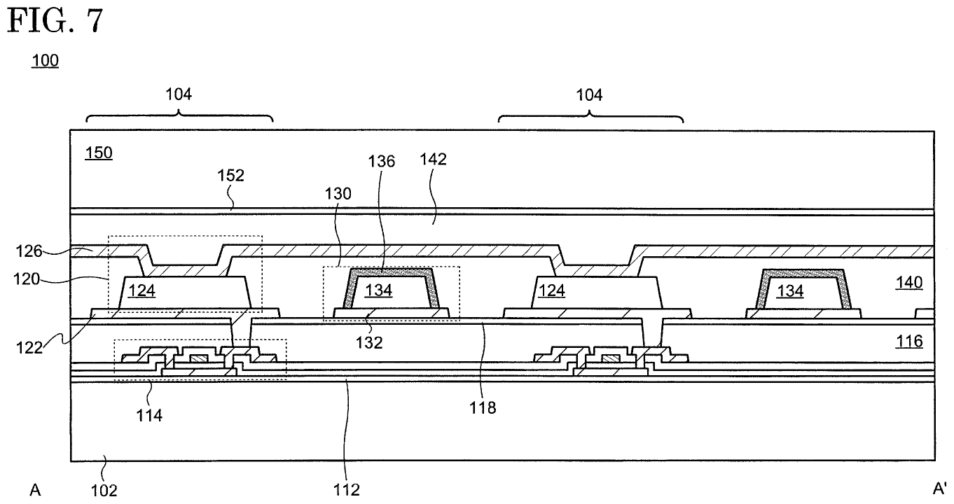

In order to more efficiently reflect the light emitted from the first stack structure 124, a reflective film 136 may be provided over the second stack structure 134 as shown in FIG. 7. The reflective film 136 is preferred to have a high reflectance with respect to visible light, and thus is configured to include a metal such as aluminum, silver, tungsten, tantalum, molybdenum, and titanium. Alternatively, the reflective film 136 may be composed of a dielectric multilayer film which is an alternating layer structure of thin films of materials with different refractive indices, such as titanium oxide and silicon oxide. The reflective film 136 may be in contact with the lower electrode 132 as shown in FIG. 7 or with the protective insulating film 118 or the leveling film 116, although not illustrated. The reflective film 136 is also covered by the partition wall 140 and is spaced away from the common electrode 126.

### 5. Other Component

As an optional component, an encapsulating film 142 may be provided over the common electrode 126. The encapsulating film 142 is provided in order to prevent impurities such as water from entering the light-emitting element 120 and the pixel circuit. The encapsulating film 142 includes, for example, a silicon-containing inorganic compound such as silicon nitride and silicon oxide and/or a polymer such as an acrylic resin, an epoxy resin, and a polyimide resin. For example, a structure may be employed in which a film containing a polymer is sandwiched by films containing a silicon-containing inorganic compound. As an additional optional structure, an overcoat 152 in contact with the counter substrate 150 may be provided in order to prevent the entrance of impurities from the counter substrate 150.

### 6. Modified Examples

The display device 100 may also be configured so that the light generated in the pixels 104 is extracted through the substrate 102. In this case, a glass substrate, a quartz substrate, or a substrate containing a polymer is used as the substrate 102 to transmit visible light. In addition, the pixel electrode 122 is formed to include a conductive oxide such as ITO and IZO transmitting visible light, while the common electrode 126 is configured to include a metal such as silver and aluminum to reflect the light emitted from the first stack structure 124 toward the pixel electrode 122 side.

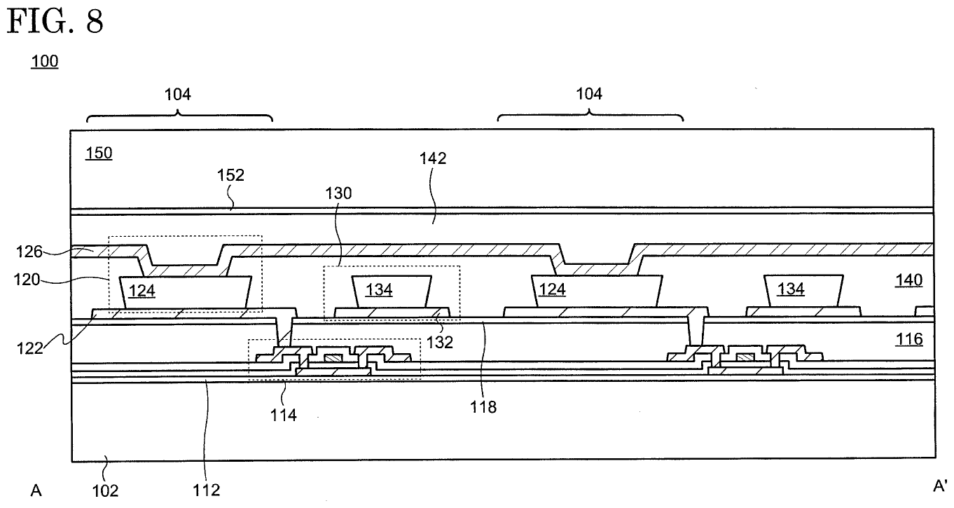

Here, it is preferable to configure the second stack structure 134 to have an inverse tapered shape so that the width increases with increasing distance from the lower electrode 132 as shown in FIG. 8 in order to efficiently reflect the light emitted from the first stack structure 124 to the pixel electrode 122 side with the reflective element 130. Since the first stack structure 124 and the second stack structure 134 are formed in the same process, the first stack structure 124 also has an inverse tapered shape.

As described above, the plurality of reflective elements 130 is provided in the display device 100 as a mechanism to reflect the light obtained in the pixels 104 toward the counter substrate 150 side or the substrate 102 side along with the plurality of pixels 104. As a result, the display device 100 exhibits high efficiency and small power consumption, because the light which cannot be utilized in conventional display devices due to the total reflection can be used for display. In addition, since the power required to obtain the same luminance can be reduced, the burden on each light-emitting element 120 is reduced, and as a result, the reliability of the display device 100 can be improved.

Although the display device is explained as an embodiment of the present invention, a similar structure can be used for a lighting device. In this case, a simpler structure can be adopted for the light-source circuit corresponding to the pixel circuit, where a driver circuit or an external switch may be used to control the power and signals supplied to light-source elements corresponding to the pixels 104 without providing transistors nor capacitive elements.

### Second Embodiment

In this embodiment, a display device 200 having a different structure from the display device 100 described in the First Embodiment is explained. An explanation of the structures the same as or similar to those described in the First Embodiment may be omitted.

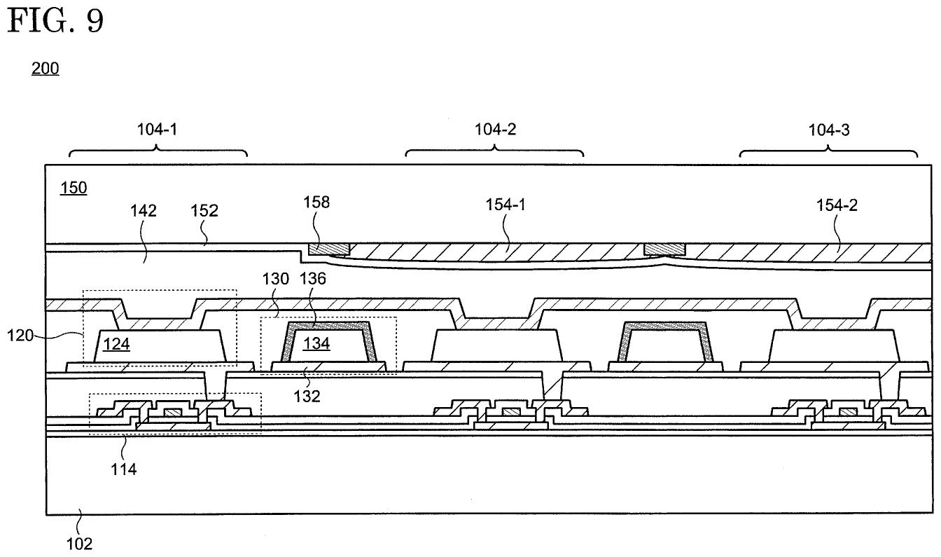

FIG. 9 shows a schematic cross-sectional view of the display device 200. In FIG. 9, three pixels 104-1 through 104-3 are demonstrated. A difference of the display device 200 from the display device 100 is that a color conversion layer 154 is provided in at least some of the pixels 104, thereby enabling full color display.

Specifically, a light-emitting element 120 capable of emitting ultraviolet to blue light is provided in each pixel 104 of the display device 200. More specifically, the light-emitting element 120 capable of emitting light having at least one peak in the wavelength region equal to or longer than 250 nm and equal to or shorter than 450 nm is provided in each pixel 104. Such short wavelength light can be realized by using gallium nitride, zinc selenide, or the like in the functional layer functioning as the emission layer. In addition, the color conversion layers 154-1 and 154-2 are respectively disposed in the pixels for obtaining green light (in this case, the pixel 104-2) and red light (in this case, pixel 104-3). The color conversion layer 154 is provided, for example, between the counter substrate 150 and the overcoat 152 or between the encapsulating film 142 and the overcoat 152 so as to overlap the first stack structure 124 of the corresponding pixel 104. The color conversion layers 154-1 and 154-2 include color conversion materials absorbing the light emitted from the light-emitting element 120 and providing green and red emission, respectively, as well as a resin for dispersing the color conversion materials. As the color conversion materials, an organic or inorganic light-emitting material or quantum dots may be used. Quantum dots include cadmium selenide, cadmium sulfide, cadmium telluride, zinc selenide, zinc oxide, zinc sulfide, and the like with particle sizes ranging from several nm to 20 nm. Note that the color conversion layer 154 may or may not be provided in the pixel to obtain the blue light emission (in this case, the pixel 104-1). When the color conversion layer 154 is provided in the pixel to obtain the blue light emission, a color conversion layer which absorbs the light emitted from the light-emitting element 120 and provides blue light emission may be used.

In this configuration, the light obtained from the light-emitting element 120 in the pixel 104-1 is extracted directly or through the color conversion layer which is not illustrated but provides the blue light emission. In contrast, the light obtained from the light-emitting element 120 is converted to green and red light by the color conversion layers 154-1 and 154-2 in the pixels 104-2 and 104-3, respectively. As a result, a full-color display can be performed by controlling the driving of the pixels 104.

In order to avoid mixing of the color from adjacent pixels 104, a light-shielding film (black matrix) 158 overlapping the reflective element 130 may be provided as an optional component. The light-shielding film 158 overlaps a part or the whole of the second stack structure 134 in the vertical direction. Although not illustrated, each light-emitting element 120 may be configured to be capable of emitting white light, and a color filter may be provided in each pixel in place of the color conversion layer 154.

The display device 200 having the aforementioned structure can be used as a display device capable of full color display. It is also possible to apply the structure described above to a lighting device to provide lighting capable of changing lighting colors.

### Third Embodiment

In this embodiment, a manufacturing method of the display device and the lighting device according to an embodiment of the present invention is explained. Here, a manufacturing method for the display device 100 described in the First Embodiment is explained as an example. An explanation of the structures the same as or similar to those described in the First or Second Embodiment may be omitted. The display device 100 can be manufactured by forming a variety of conductive films, insulating films, and semiconductor films over the substrate 102 and patterning these films as appropriate. A detailed description is omitted because the structures up to the protective insulating film 118 can be formed using known methods and materials.

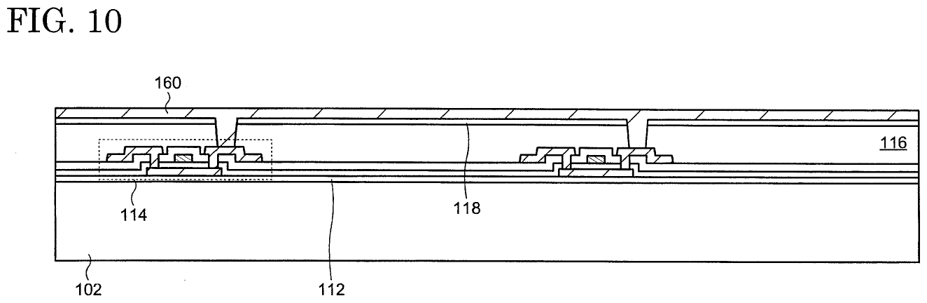

The pixel circuit including the transistor 114 is formed over the substrate 102 over which the leveling film 116 and the protective insulating film 118 are formed (see FIG. 5 and FIG. 7). Then, etching is carried out to form the openings reaching the transistors 114 in the leveling film 116 and the protective insulating film 118, and a conductive film 160 electrically connected to the transistors 114 through the openings is formed over the entire display region (FIG. 10). The conductive film 160 may be formed using the metal organic chemical vapor deposition (MOCVD) method which is one of the chemical vapor deposition (CVD) methods or a sputtering method. The conductive film 160 provides the pixel electrode 122 and the lower electrode 132 by the subsequent process. Therefore, the conductive film 160 is formed so that the composition and the layer structure thereof are identical to the composition and the layer structure employed in the pixel electrodes 122 and the lower electrodes 132, respectively.

The first stack structure 124 and the second stack structure 134 respectively formed in the pixel 104 and the reflective element 130 are formed by a transfer method. That is, a stack structure providing the first stack structure 124 and the second stack structure 134 is formed over a transfer substrate 170 different from the substrate 102, and then the stack structure is transferred onto the conductive film 160. Thus, the stacking order of the functional layers is reversed between over the transfer substrate 170 and over the substrate 102.

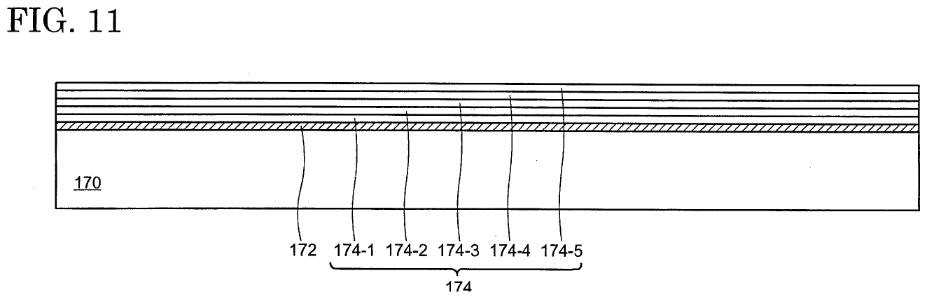

Specifically, a peeling layer 172 is first formed over the transfer substrate 170 as shown in FIG. 11. The transfer substrate 170 may be any substrate which transmits the laser light used to decompose the peeling layer 172 in the laser lift-off (LLO) method described below. Specifically, a sapphire substrate, a glass substrate, or a quartz substrate may be used. The peeling layer 172 is a film including a material which is decomposed by the laser light, and a film containing GaN is exemplified. The thickness of the peeling layer 172 may be appropriately selected in the range equal to or greater than 10 nm and equal to or less than 30 nm. Thereafter, the functional layers providing the first stack structure 124 and the second stack structure 134 are sequentially formed over the peeling layer 172. Since the stacking order of the layers is reversed by the transfer method, the functional layers 174-1, 174-2, 124-3, 124-4, and 124-5 having the same composition and structure as the functional layers 124-5, 124-4, 124-3, 124-2, and 124-1, respectively, are stacked in order from the transfer substrate 170 side when the first stack structure 124 has the functional layers 124-1, 124-2, 124-3, 124-4, and 124-5 in order from the substrate 102 side, for example.

The formation of the peeling layer 172 and the functional layers 174 may be performed using a MOCVD method or a sputtering method. Each of the peeling layer 172 and the functional layers 174 may have a single crystal structure, a polycrystalline structure, or a microcrystalline structure.

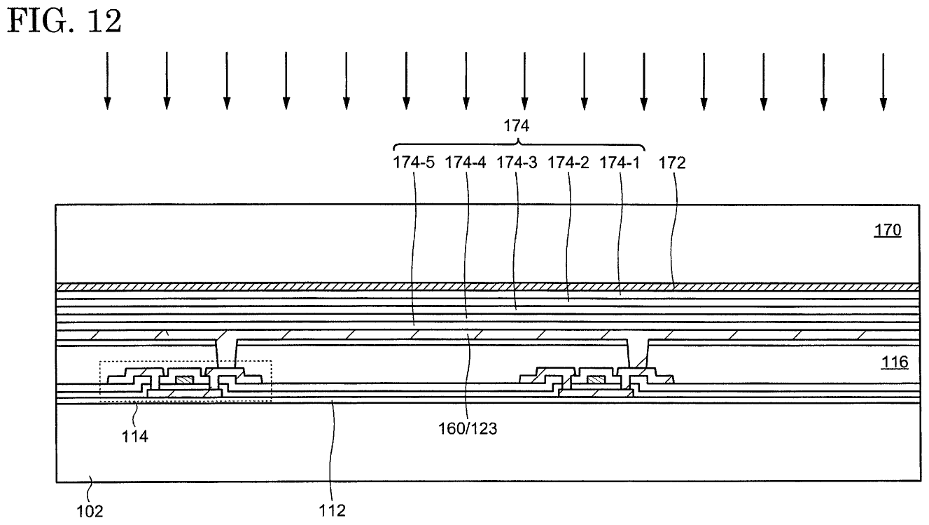

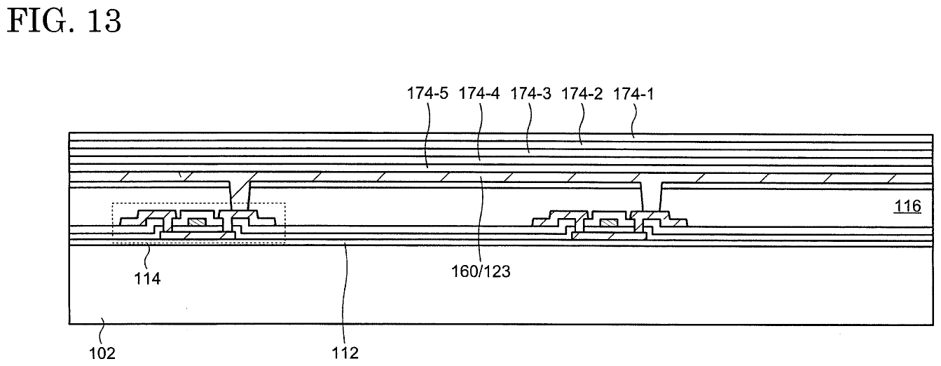

The functional layers 174 and the conductive film 160 are then bonded to each other (FIG. 12). The conductive adhesive layer 123 may be formed over the conductive film 160 before bonding. Specifically, the conductive adhesive layer 123 may be formed by applying solder or applying and sintering a paste in which metal particles such as gold, silver, copper, and nickel are dispersed in a resin. The LLO method is then applied to peel off the transfer substrate 170. Specifically, a laser beam is applied through the transfer substrate 170 as represented by the arrows in FIG. 12. The wavelength of the laser light may be selected from the wavelength which can be absorbed by the pealing layer 172, and a KrF excimer laser (248 nm) may be used, for example. This process decomposes the peeling layer 172 to result in the loss of adhesion between the transfer substrate 170 and the functional layers 174, by which the transfer substrate 170 can be peeled from the functional layers 174 (FIG. 13).

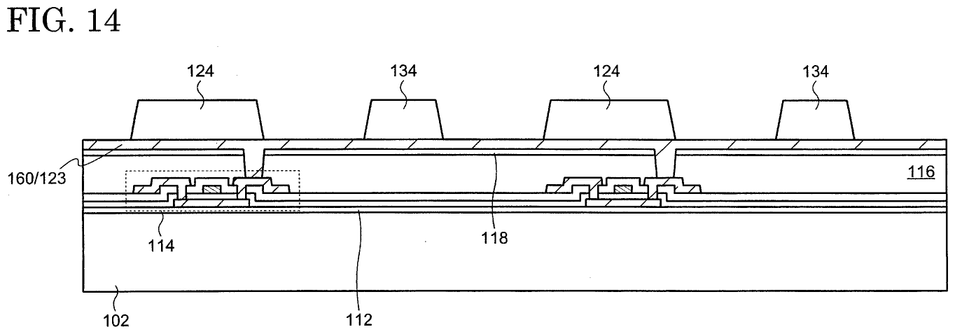

The functional layers 174 are then processed by photolithography. That is, a resist mask which is not illustrated is formed over the functional layers 174 as appropriate, the functional layers 174 exposed from the resist mask is removed by dry etching or wet etching, and then the resist mask is removed. As a result, the first stack structure 124 and the second stack structure 134 are formed over the conductive film 160 (FIG. 14). It is preferred to perform the etching so that the resulting first stack structure 124 and second stack structure 134 have a tapered shape.

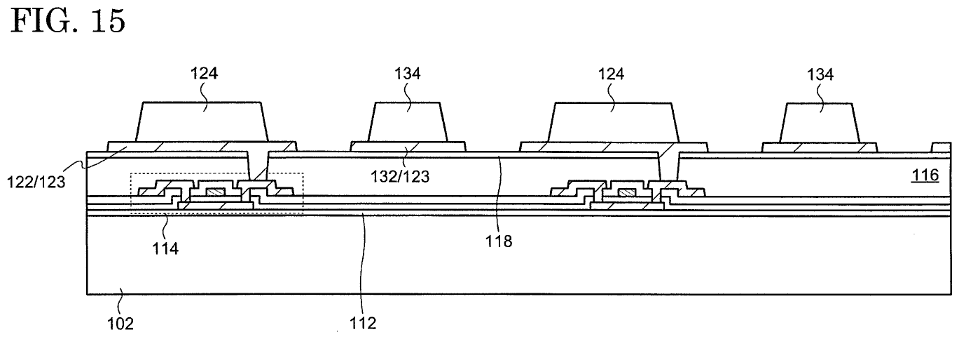

The conductive film 160 is then processed by photolithography. That is, a resist mask (not illustrated) covering the first stack structure 124 and the second stack structure 134 is formed over the conductive film 160 as appropriate, the conductive film 160 exposed from the resist mask is removed by dry etching or wet etching, and then the resist mask is removed. As a result, the pixel electrode 122 overlapping the first stack structure 124 and maintaining the electrical connection with the transistor 114 is formed as well as the lower electrode 132 overlapping the second stack structure 134 and electrically separated from all of the pixel circuits including the transistors 114 are formed (FIG. 15).

Although not illustrated, when the first stack structure 124 and the second stack structure 134 are provided with a reverse tapered shape (see FIG. 8.), the functional layers 174 are processed over the transfer substrate 170 to form the first stack structure 124 and the second stack structure 134 having a tapered shape before bonding the functional layer 174 and the conductive film 160 to each other. Furthermore, the conductive film 160 is processed by etching in advance to form the pixel electrode 122 and the lower electrode 132 before bonding the transfer substrate 170 and the substrate 102 to each other. Thereafter, the first stack structure 124 and the second stack structure 134 may be bonded to the pixel electrode 122 and the lower electrode 132, respectively, and the transfer substrate 170 may be peeled off.

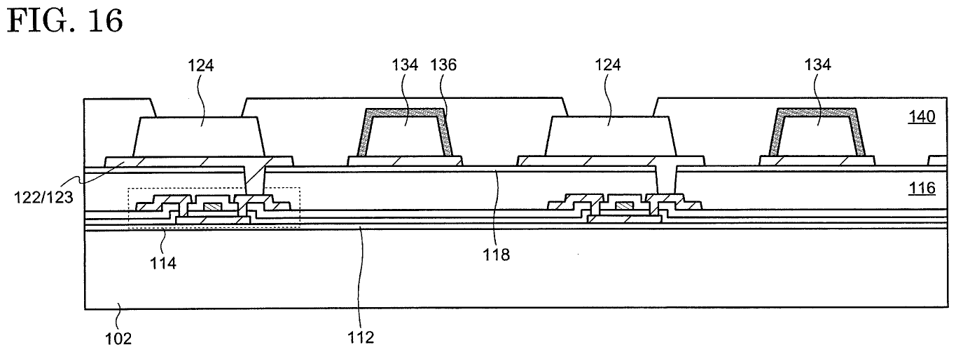

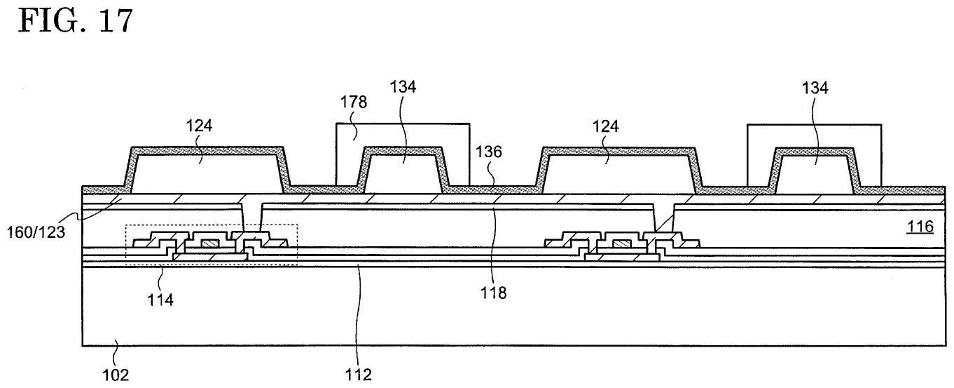

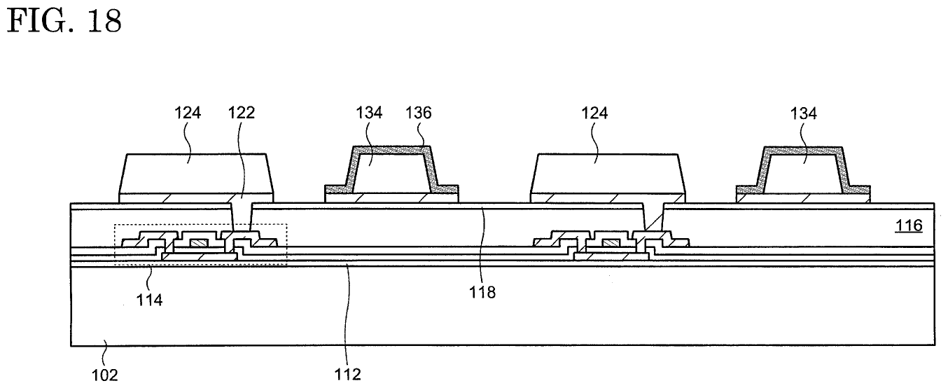

When providing the reflective film 136, the reflective film 136 is provided to cover the first stack structure 124 and the second stack structure 134. The reflective film 136 may be formed by applying a CVD method or a sputtering method. Then, the plurality of reflective films 136 overlapping the second stack structures 134 can be formed by forming a resist mask which is not illustrated, performing etching, and removing the resist mask (FIG. 16). Alternatively, the reflective film 136 may be provided to cover the first stack structure 124, the second stack structure 134, and the conductive film 160 before processing the conductive film 160 as shown in FIG. 17, the resist mask 178 may be then formed, and the conductive film 160 and reflective film 136 may be processed by etching simultaneously or stepwise using the resist mask 178 and the first stack structure 124 as masks (FIG. 18). In this case, the side surfaces of the conductive film 160 and the reflective film 136 may be located over the same plane, and a side of the bottom surface of the first stack structure 124 and a side of the top surface of the pixel electrode 122 may match, depending on the etching conditions (i.e., the degree of side etching).

The partition wall 140 is then formed. The partition wall 140 may be formed by forming a resin having photosensitive properties, such as an acrylic resin, an epoxy resin, a polyimide resin, and a polysiloxane resin by applying a spin-coating method, an inkjet method, a printing method, or the like, followed by exposure through a photo mask, sintering, and development. The partition wall140 is formed to embed the second stack structure 134 and the reflective film 136 of the reflective element 130, cover an edge portion of the first stack structure 124 of the pixel 104, and expose a portion of the first stack structure 124 (FIG. 16).

After that, the common electrode 126 is formed using a sputtering method or the like, and the encapsulating film 142 is further provided. The color conversion layer 154, the color filter, and the overcoat 152 are provided over the counter substrate 150, and the counter substrate 150 and the substrate 102 are fixed to each other using an adhesive, by which the display device 100 can be manufactured (FIG. 5 and FIG. 7). Since the formation of the common electrode 126 and subsequent processes can be performed using known methods and materials, a detailed description is omitted.

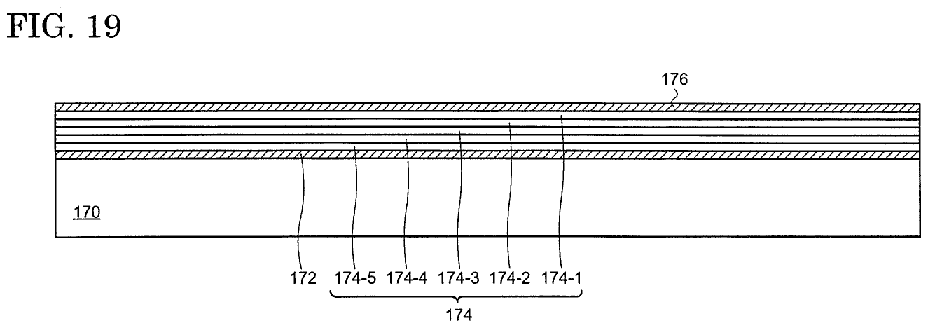

In the method described above, the first stack structure 124 and the second stack structure 134 are formed by transferring the functional layers 174 formed over the transfer substrate 170 onto the substrate 102. That is, the manufacturing method described above includes one transfer process. However, a plurality of transfer processes may be performed. In this case, the peeling layer 172 is formed over the transfer substrate 170, and the functional layers 174 are formed over the peeling layer 172 as shown in FIG. 19. The stacking order of the functional layers 174 is the same as the stacking order of the functional layers included in the first stack structure 124 and the second stack structure 134 over the substrate 102. Since the transfer process is performed twice, it is preferable to provide a peeling layer 176 over the functional layers 174.

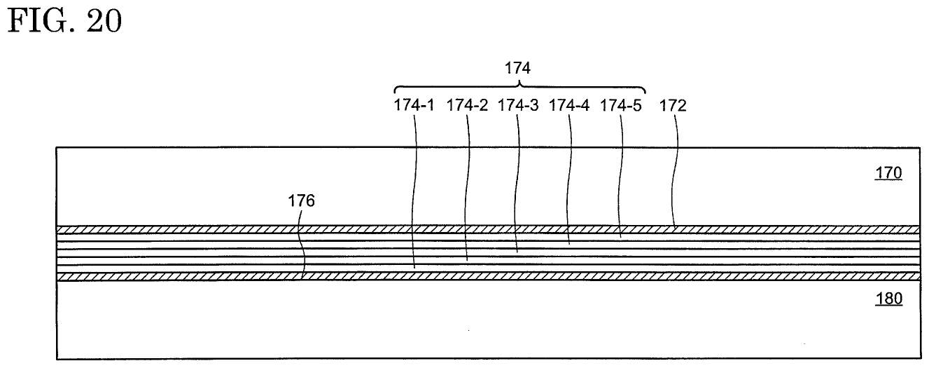

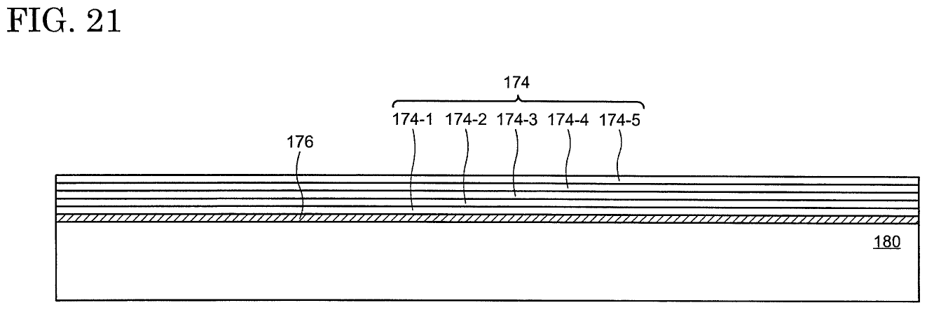

After that, the functional layers 174 are bonded to a different transfer substrate (hereafter, relay substrate) 180 from the transfer substrate 170 (FIG. 20). Furthermore, the peeling layer 172 is decomposed by laser irradiation from the transfer substrate 170 side, and the transfer substrate 170 is peeled, thereby providing the functional layers 174 stacked over the relay substrate 180 (FIG. 21). Thereafter, the relay substrate 180 and the substrate 102 may be bonded to each other so that the functional layers 174 are sandwiched between the relay substrate 180 and the substrate 102, and then the relay substrate 180 may be peeled using the LLO method. In the case of providing a reverse tapered shape to the first stack structure 124 and the second stack structure 134, the functional layers 174 over the relay substrate 180 may be processed to form a tapered shape, and then the relay substrate 180 may be bonded to the substrate 102 over which the pixel electrode 122 and the lower electrode 132 are formed in advance. Since the processes after this process are the same as the processes described above, the explanation thereof is omitted.

In the manufacturing method according to an embodiment of the present invention, the reflective element 130 for improving the light extraction efficiency from the pixel 104 is formed at the same time as the pixel 104. In other words, there is no need to add a separate new process for providing the reflective element 130. Therefore, it is possible to manufacture highly efficient display devices and lighting devices without increasing manufacturing costs.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the display device of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A display device comprising:
a substrate; and
a plurality of pixels and at least one reflective element located over the substrate, each of the plurality of pixels comprising:
a pixel circuit; and
a light-emitting element including a pixel electrode electrically connected to the pixel circuit, a first stack structure over the pixel electrode, and a common electrode over the first stack structure,
wherein the at least one reflective element comprises:
a lower electrode;
a second stack structure over the lower electrode;
a reflective film overlapping the second stack structure, and
each of the first stack structure and the second stack structure includes a plurality of inorganic semiconductor layers.

2. The display device according to claim 1,
wherein the at least one reflective element is electrically floated.

3. The display device according to claim 1,
wherein the at least one reflective element includes a plurality of reflective elements, and
the plurality of pixels and the plurality of reflective elements are arranged in a matrix shape as a whole.

4. The display device according to claim 3,
wherein the plurality of pixels and the plurality of reflective elements alternate with each other in a row direction or a column direction of the matrix shape.

5. The display device according to claim 3,
wherein the plurality of pixels is sandwiched by two adjacent reflective elements in a row direction or a column direction of the matrix shape.

6. The display device according to claim 1,
wherein the at least one reflective element has an opening surrounding one or more of the plurality of pixels.

7. The display device according to claim 1,
wherein the reflective film is spaced away from the common electrode through a partition wall.

8. The display device according to claim 7,
wherein the partition wall embeds the reflective film and the second stack structure of the at least one reflective element and covers edge portions of the first stack structures of the plurality of pixels.

9. The display device according to claim 1,
wherein widths of the first stack structure and the second stack structure decrease with increasing distance from the substrate.

10. The display device according to claim 1,
wherein the first stack structure and the second stack structure each contain a gallium-based material.

11. A manufacturing method of a display device, the manufacturing method comprising:
forming a plurality of pixel circuits over a substrate;
forming, over the plurality of pixel circuits, a leveling film having a plurality of openings;
forming, over the leveling film, a conductive film electrically connected to the plurality of pixel circuits through the plurality of openings;
bonding a stacking structure located over a first transfer substrate and containing a plurality of inorganic semiconductor layers to the conductive film;
peeling the first transfer substrate;
processing the stacking structure to form a plurality of first stack structures and at least one second stack structure;
processing the conductive film to form:
a plurality of pixel electrodes respectively overlapping the plurality of first stack structures and electrically connected to the plurality of pixel circuits, respectively; and
a lower electrode overlapping the at least one second stack structure and electrically separated from each of the plurality of pixel circuits;
forming a reflective film overlapping the at least one second stack structure;
forming a partition wall embedding the at least one second stack structure and the reflective film and covering edge portions of the plurality of first stack structures; and
forming, over the plurality of first stack structures and the at least one second stack structure, a common electrode electrically connected to the plurality of first stack structures and spaced away from the reflective film.

12. The manufacturing method according to claim 11,
wherein the substrate is a grass substrate or a quartz substrate, and
the first transfer substrate is a grass substrate, a single crystalline silicon substrate, or a single crystalline sapphire substrate.

13. The manufacturing method according to claim 11, further comprising irradiating the stacking structure with laser light through the first transfer substrate before peeling the first transfer substrate.

14. The manufacturing method according to claim 11,
wherein the processing of the stacking structure is performed so that widths of the plurality of first stack structures and the at least one second stack structure decrease with increasing distance from the substrate.

15. The manufacturing method according to claim 11,
wherein the at least one second stack structure includes a plurality of second stack structures, and
the processing of the stacking structure is performed so that the plurality of first stack structures and the plurality of second stack structures are arranged in a matrix shape as a whole.

16. The manufacturing method according to claim 15,
wherein the processing of the stacking structure is performed so that the plurality of first stack structures and the plurality of second stack structures alternate with each other in a row direction or a column direction of the matrix shape.

17. The manufacturing method according to claim 15,
wherein the processing of the stacking structure is performed so that two or more of the first stack structures selected from the plurality of first stack structures are sandwiched by adjacent two second stack structures.

18. The manufacturing method according to claim 11,
wherein the processing of the stacking structure is performed so that the at least one second stack structure has an opening surrounding at least one of the plurality of first stack structures.

19. The manufacturing method according to claim 11, further comprising:
forming the stacking structure over a second transfer substrate; and
transferring the stacking structure from the second transfer substrate onto the first transfer substrate.

20. The manufacturing method according to claim 11, wherein the first stack structure and the at least one second stack structure each contain a gallium-based material.
